(19) United States
(12) Patent Application Publication
(10) Pub. No.: US 2025/0391776 A1
(43) Pub. Date: Dec. 25, 2025

(54) Semiconductor Device and Method of Making Advanced Chiplet Bridge Die with Carrier

(71) Applicant: JCET STATS ChipPAC Korea Limited, Incheon (KR)

(72) Inventors: SeungHyun Lee, Incheon (KR); Yeojun Yun, Incheon (KR); HeeSoo Lee, Incheon (KR)

(73) Assignee: JCET STATS ChipPAC Korea Limited, Incheon (KR)

(21) Appl. No.: 18/753,960

(22) Filed: Jun. 25, 2024

(51) Int. Cl. H01L 23/538; H01L 23/00; H01L 23/498; H01L 25/065

(52) U.S. Cl. CPC H01L 23/5381; H01L 23/49816; H01L 23/49838; H01L 24/05; H01L 24/13; H01L 24/97; H01L 25/0652; H01L 2224/05005; H01L 2224/05025; H01L 2224/13009; H01L 2224/13026; H01L 2224/97; H01L 2924/01029; H01L 2924/0665; H01L 2924/15311; H01L 2924/182

(57) ABSTRACT

A semiconductor device is formed using a semiconductor wafer. A bridge die is formed over the semiconductor wafer including a first contact pad on a first surface of the bridge die and a second contact pad on a second surface of the bridge die opposite the first surface. The semiconductor wafer is attached to a first carrier. The semiconductor wafer and first carrier are singulated to separate the bridge die and a portion of the first carrier. The bridge die is disposed over a second carrier with the bridge die between the second carrier and the portion of the first carrier. The portion of the first carrier is removed after disposing the bridge die over the second carrier.

### FIELD OF THE INVENTION

The present invention relates in general to semiconductor devices and, more particularly, to a semiconductor device and method of making an advanced chiplet bridge die with a carrier.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Bridge die can be embedded within semiconductor substrates to provide a tighter pitch of interconnect and higher total bandwidth than the substrate itself can provide. However, even bridge die have limits, and creating bridge die with tighter pitches can only take device manufacturers so far. Therefore, a need exists for a semiconductor device and method of making an advanced chiplet bridge die with a carrier.

### BRIEF DESCRIPTION OF THE DRAWINGS

FIGS. 1a-1g illustrate a process of forming a double-sided bridge die with a temporary carrier;

FIGS. 2a-2p illustrate forming a chiplet with the double-sided bridge die;

FIGS. 3a-3f illustrate forming a double-sided bridge die with pillar interconnects;

FIGS. 4a-4e illustrate forming a chiplet with the double-sided bridge die having pillar interconnects; and

FIGS. 5a and 5b illustrate an electronic device with the chiplet.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

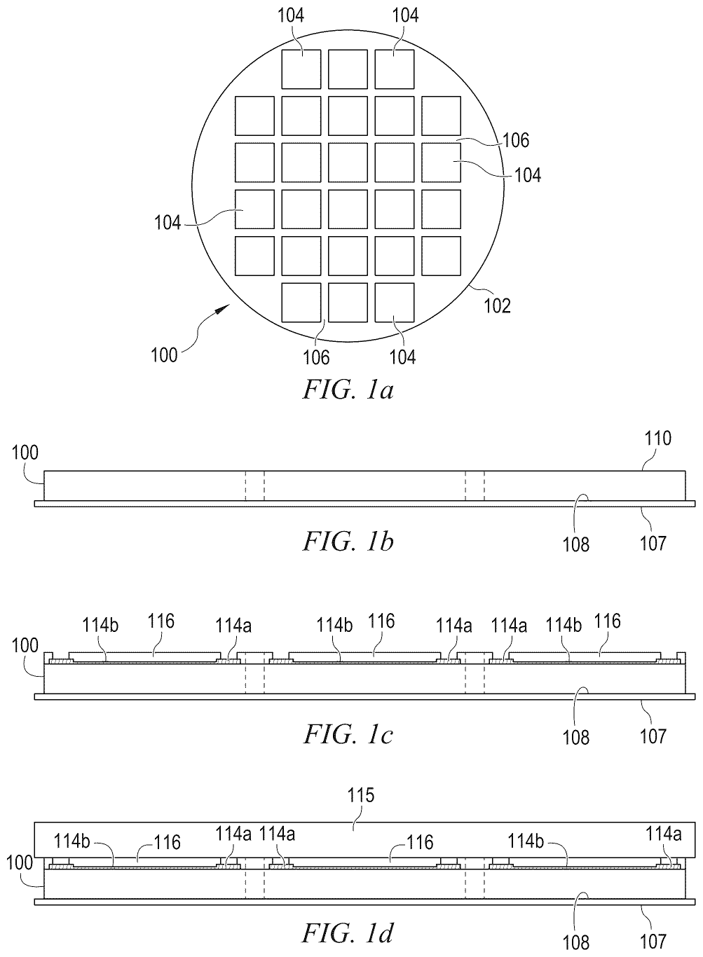

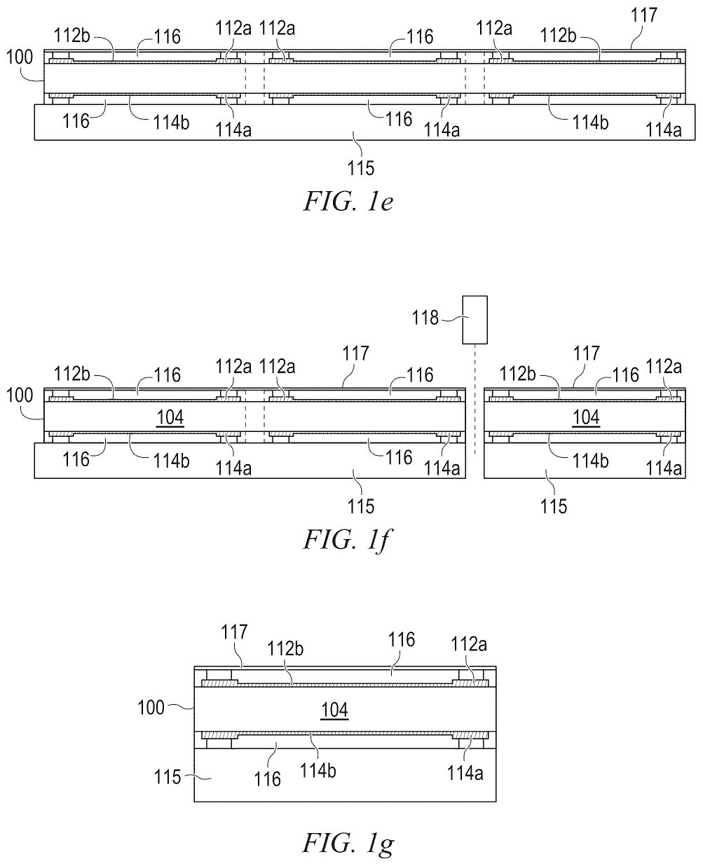

FIGS. 1a-1g illustrate a process of forming a double-sided bridge die for inclusion in a chiplet design. FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. Non-silicon substrates are used in other embodiments, e.g., glass, insulating material, or a PCB material. Semiconductor materials are more commonly used due to the maturity of manufacturing processes for forming fine pitched interconnects on silicon.

A plurality of bridge die 104 is formed on wafer 100 separated by a non-active, inter-die wafer area or saw street 106. Saw street 106 provides cutting areas to singulate semiconductor wafer 100 into individual bridge die 104. In one embodiment, semiconductor wafer 100 has a width or diameter of 100-450 millimeters (mm). Wafer 100 begins as a single uniform body of semiconductor material. The squares labelled 104 in FIG. 1a are only to show where bridge die 104 will be formed. FIG. 1b shows a cross-sectional view of a portion of semiconductor wafer 100 prior to forming bridge die 104. Wafer 100 is placed on a carrier 107 for processing.

A conductive layer 114 is formed over surface 110 of semiconductor wafer 100 in FIG. 1c. Conductive layer 114 is formed using physical vapor deposition (PVD), chemical vapor deposition (CVD), electrolytic plating, electroless plating, sputtering, or other suitable metal deposition process. Conductive layer 114 can be one or more layers of aluminum (Al), copper (Cu), tin (Sn), nickel (Ni), gold (Au), silver (Ag), or other suitable electrically conductive material.

Conductive layer 114 is patterned to include contact pads 114a and conductive traces 114b. To operate as a bridge die, bridge die 104 includes contact pads 114a near two opposing edges of each bridge die. Each contact pad 114a is paired with a contact pad on the opposite edge of the bridge die 104 by a conductive trace 114b. Conductive trace 114b is drawn as thinner than contact pads 114a simply to illustrate the concept of the trace being very fine pitched. In practice, conductive layer 114 is more commonly of uniform thickness. Passivation or solder resist layer 116 is formed over conductive layer 114 to protect the conductive layer. Solder resist layer 116 can be formed using any of the methods and materials described below for insulating layers generally. Openings are formed through solder resist layer 116 to expose contact pads 114a.

In FIG. 1d, a carrier 115 is mounted onto wafer 100 opposite carrier 107. Carrier 115 is attached to insulating layer 116 using a UV, laser, thermal or other type of releasable adhesive in some embodiments. The adhesive layer can be a liquid, tape, or other suitable form. Carrier 115 can be another semiconductor substrate similar to wafer 100, an insulating board formed using any of the materials described below for insulating layers, a sheet of conductive material, such as copper or aluminum, PCB material such as polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics, beryllium oxide, glass, or other suitable low-cost, rigid material for structural support.

In FIG. 1e, semiconductor wafer 100 is flipped and supported by carrier 115, which is now disposed under the semiconductor wafer. Carrier 107 is removed. A conductive layer 112 is formed over surface 108 of semiconductor wafer 100. Conductive layer 112 is formed using the methods and materials described above for conductive layer 114.

Conductive layer 112 is patterned to include contact pads 112a and conductive traces 112b. To operate as a bridge die, bridge die 104 includes contact pads 112a near two opposing edges of each bridge die. Each contact pad 112a is paired with a contact pad on the opposite edge of the bridge die 104 by a conductive trace 112b. Solder resist layer 116 is formed over surface 108 to protect conductive layer 112. Solder resist layer 116 can be formed using any of the methods and materials described below for insulating layers generally. Openings are formed through solder resist layer 116 to expose contact pads 112a.

An adhesive layer 117 is disposed over insulating layer 116 and wafer 100 opposite carrier 115. Adhesive layer 117 is an adhesive tape in one embodiment. A protective film or backing tape can remain on adhesive layer 117 until bridge die 104 is installed in a subsequent step.

When bridge die 104 is incorporated into a semiconductor package, e.g., a chiplet or system-in-package, two other semiconductor die will be disposed over the opposing edges of bridge die 104. Each overlying semiconductor die will be connected to one side of bridge die 104 using contact pads 112a and 114a, and then the bridge die will interconnect the two overlying semiconductor die to each other by conductive traces 112b and 114b. Bridge die 104 is a double-sided bridge die by virtue of having conductive traces 112 and 114 on two opposing surfaces of the bridge die. Passivation or solder resist layers 116 are formed over surfaces 108 and 110 to protect conductive layers 112 and 114. Openings are formed through solder resist layer 116 to expose contact pads 112a and 114a.

Each bridge die 104 has two opposing and essentially identical surfaces 108 and 110, optionally containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within surfaces 108 or 110 to implement analog circuits or digital circuits, such as a digital signal processor (DSP), application specific integrated circuit (ASIC), memory, or other signal processing circuit. Bridge die 104 may also contain IPDs, such as inductors, capacitors, and resistors, for RF signal processing. In other embodiments, bridge die 104 contain no active or passive components, except for an electrically conductive layer 112 being formed over surface 108 and a conductive layer 114 being formed over surface 110.

In FIG. 1f, semiconductor wafer 100 is singulated through saw street 106 using a saw blade or laser cutting tool 118 into individual bridge die 104. The individual bridge die 104 can be inspected and electrically tested for identification of known good die or unit after singulation. FIG. 1g illustrates a completed bridge die ready for installation into a chiplet. Bridge die 104 remains attached to a portion of carrier 115. Carrier 115 is singulated along with wafer 100 so the footprint of the remaining carrier portion is equal, or approximately equal, to the size of bridge die 104. Carrier 115 supports bridge die 104 during subsequent processing to reduce warpage. Bridge die 104 is relatively soft and thin, so carrier 115 is used to handle the bridge die without causing damage.

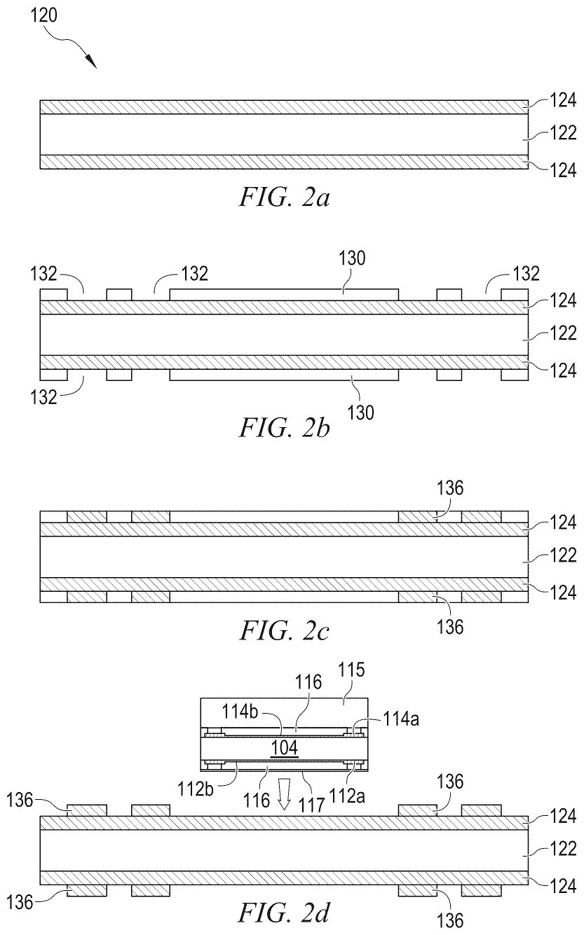

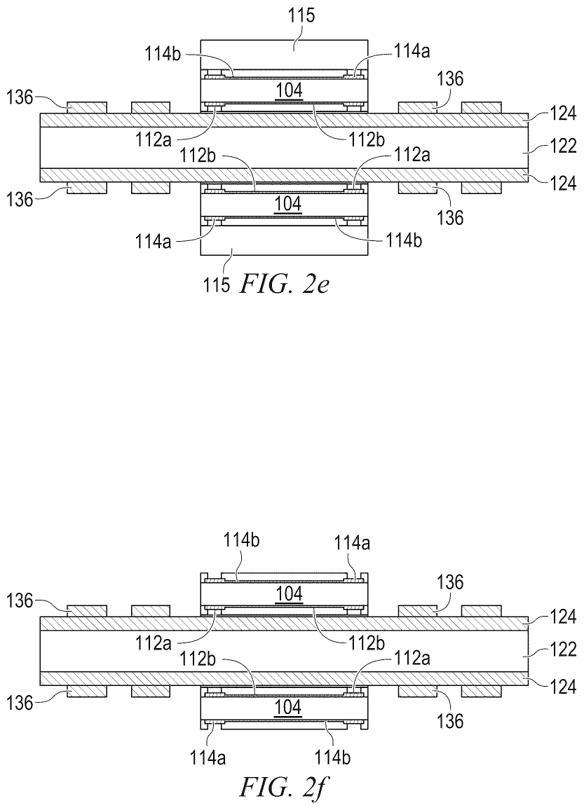

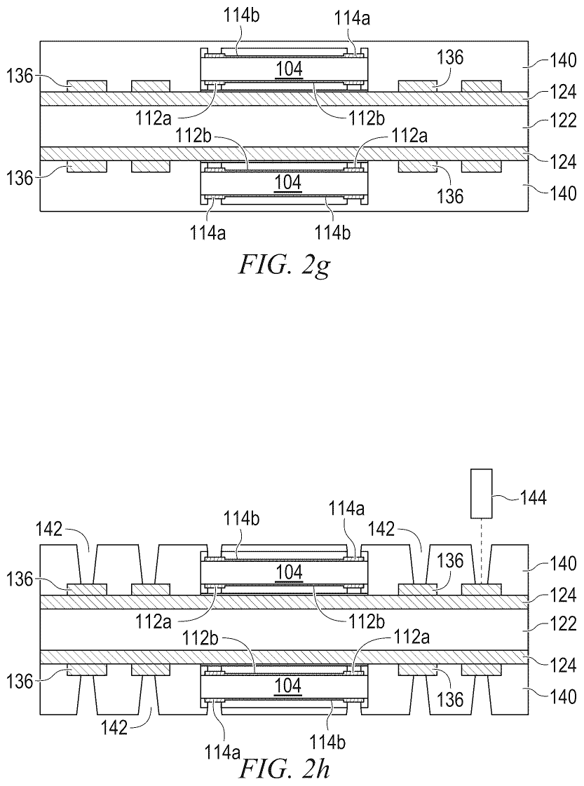

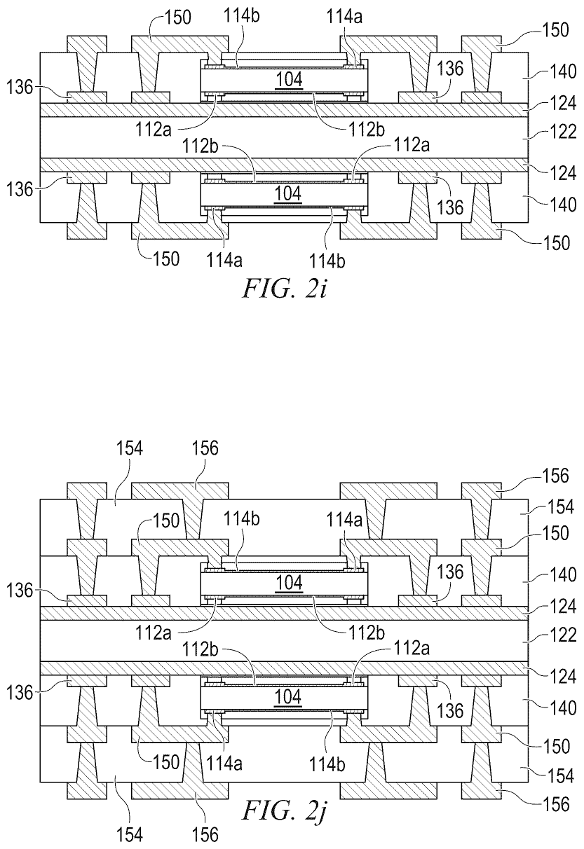

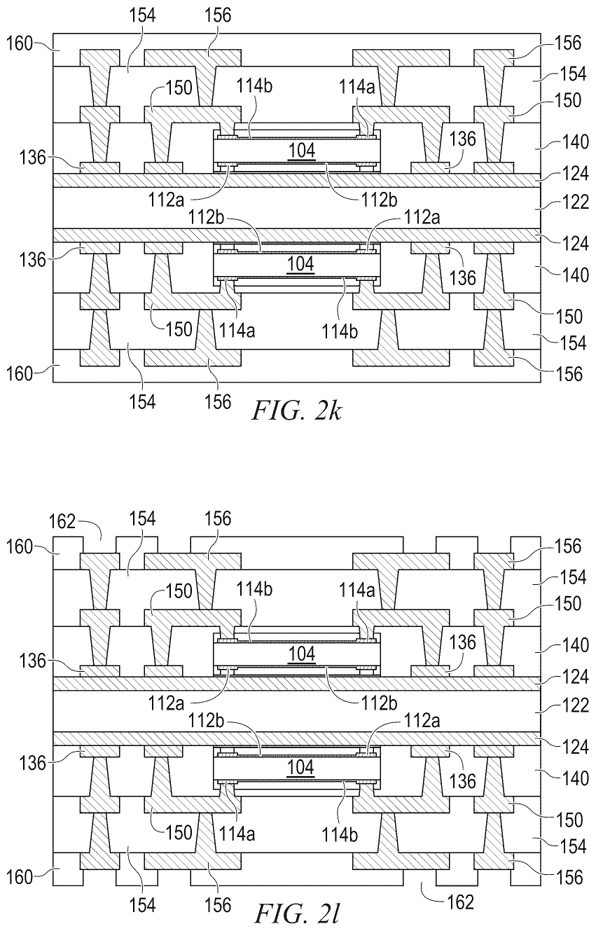

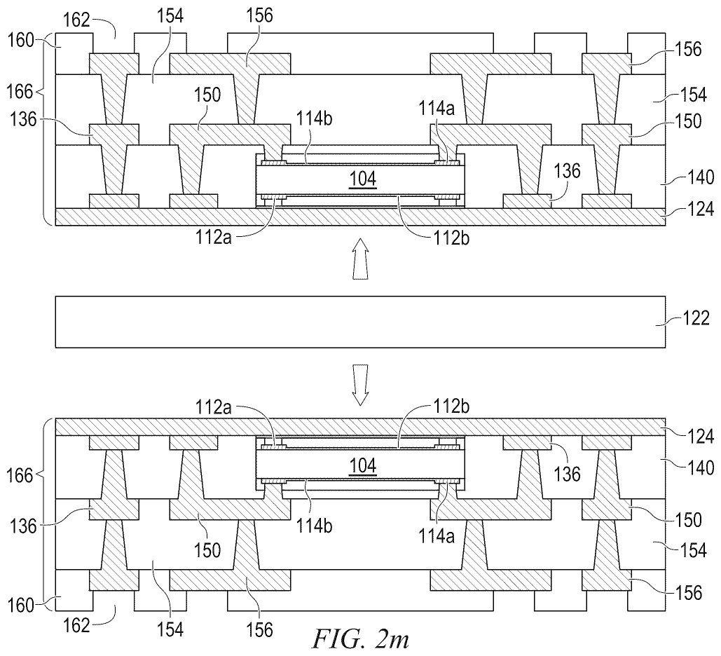

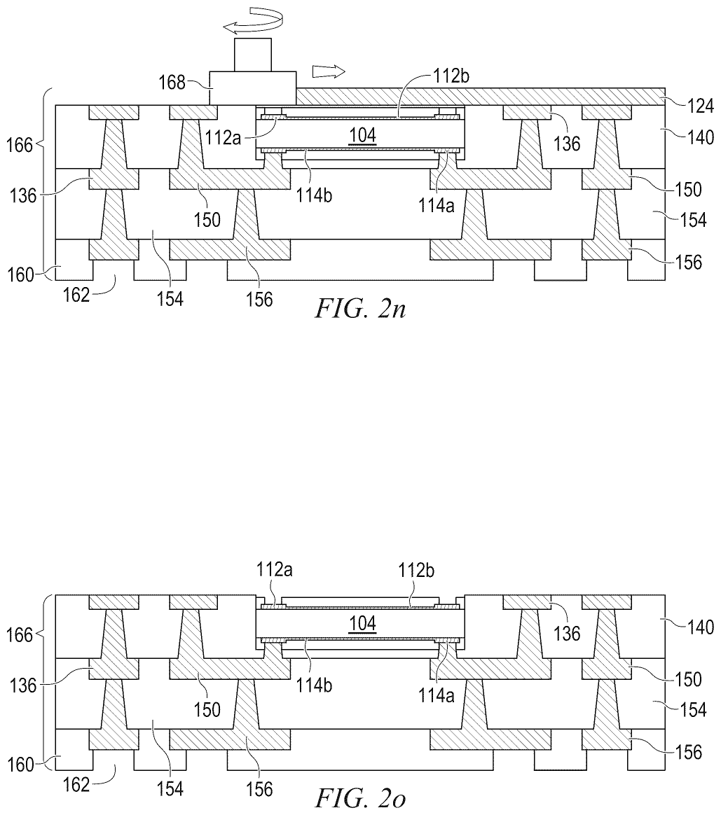

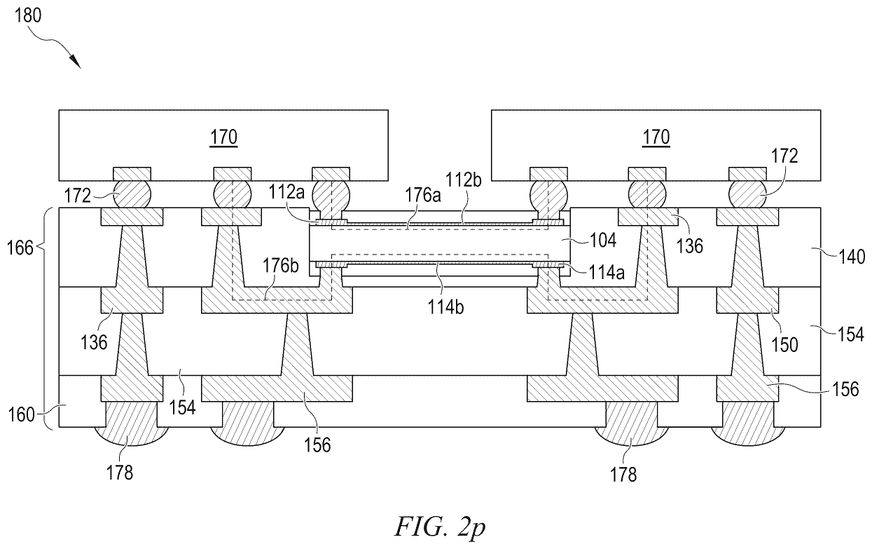

FIGS. 2a-2p illustrate a process of forming a chiplet or other type of semiconductor package with bridge die 104. FIG. 2a shows a copper-clad laminate (CCL) 120 board. CCL 120 includes a core 122 formed of a laminate or other type of printed circuit board (PCB) or substrate material with two opposing surfaces that are completely covered in copper or other conductive layers 124. Any type of temporary carrier or substrate can be used in other embodiments instead of CCL 120.

While only a single unit is shown being formed, CCL 120 is typically provided large enough for hundreds of units to be formed together before singulating near the end of the process. Each of the following manufacturing steps that occurs on both sides of CCL 120 can either be performed on both sides in unison or can be formed on one side at a time with the CCL being flipped from side-to-side between each step. In another embodiment, the illustrated steps are all performed on one side of CCL 120 before flipping the CCL and re-performing each step on the opposite surface of the CCL. There are also some embodiments, especially where another type of carrier is used, where processing only ever occurs on a single side of the carrier.

In FIG. 2b, a photoresist layer 130 is formed over conductive layer 124. Openings 132 are formed through photoresist layers 130. Openings 132 expose conductive layers 124 for deposition of conductive material to form contact pads 136 directly on the conductive layers in FIG. 2c. Photoresist layer 130 is removed in FIG. 2d leaving contact pads 136 extending above conductive layers 124. In some embodiments, contact pads 136 are part of a conductive layer that also includes conductive traces for fan-in or fan-out. The term conductive layer may refer to contact pads 136 as a group with or without conductive traces.

FIG. 2d shows a bridge die 104 being disposed onto CCL 120 after removing photoresist layer 130. Bridge die 104 are disposed with carrier 115 remaining attached and oriented away from CCL 120. Adhesive layer 117 extends from insulating layer 116 to conductive layer 124 to attach bridge die 104 to CCL 120. In other embodiments, adhesive layer 117 is disposed on CCL 120 first and then bridge die 104 is attached. In FIG. 2e, bridge die 104 are disposed on both opposing surfaces of CCL 120 with carrier 115 oriented away in each case. Bridge die 104 are disposed on conductive layers 124 between contact pads 136 using a pick and place operation.

In FIG. 2f, carriers 115 are removed or detached from bridge die 104. Carriers 115 are removed by mechanical peeling in one embodiment, with optional UV, thermal, chemical or other release method. In other embodiments, carriers 115 are removed by chemical etching, mechanical grinding, or any other suitable means. Carriers 115 were used to handle bridge die 104 between the time of manufacturing the bridge die and when the bridge die are safely on CCL 120. Carrier 115 supported and protected bridge die 104 during processing. Now that bridge die 104 is attached to CCL 102, the protection provided by carrier 115 is no longer necessary. CCL 120 sufficiently supports bridge die 104.

An insulating layer 140 is formed covering each side of CCL 120 over bridge die 104 in FIG. 2g. Insulating layers 140 contain one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 140 can be formed using PVD, CVD, printing, lamination, spin coating, spray coating, sintering, or thermal oxidation. Any insulating, passivation, or dielectric layer mentioned above or below can be formed using any of the materials or methods described for insulating layer 140. Insulating layers 140 are sheets of prepreg applied using lamination in one embodiment.

In some embodiments, insulating layer 140 is formed over bridge die 104 with carriers 115 still attached. Then, carriers 115 are removed by backgrinding both insulating layer 140 and the carriers together.

In FIG. 2h, openings 142 are formed through insulating layers 140 to expose contact pads 136 for subsequent electrical interconnect. Openings 142 are formed by laser-direct ablation (LDA) using a laser 144, by mechanical etching, by chemical etching, or by another suitable method. Openings 142 also expose contact pads 114b of bridge die 104. In other embodiments, film-assisted molding or another method is used to form insulating layer 140 without covering bridge die 104.

A conductive layer 150 is formed over insulating layer 140 in FIG. 2i. Conductive layer 150 is formed using any of the materials and methods described above for conductive layers 112 and 114. Conductive layer 150 fills openings 142 to provide conductive vias for vertical interconnect through insulating layer 140. Conductive layer 150 also includes conductive traces for horizontal interconnect across the surface of insulating layer 140. In particular, conductive layer 150 includes conductive traces and conductive vias to electrically connect some contact pads 136 to contact pads 114a of bridge die 104. Other portions of conductive layer 150 only provide vertical interconnect and a contact pad for subsequent electrical interconnect, or optionally conductive traces to fan-in or fan-out electrical connections without connecting to bridge die 104.

In FIG. 2j, an additional insulating layer 154 and conductive layer 156 are formed over insulating layer 140 and conductive layer 150. Insulating layer 154 is formed of similar materials and methods as described above for insulating layer 140. Conductive layer 156 is formed of similar materials and methods as described above for conductive layer 150. Conductive layer 156 is patterned to include conductive vias through insulating layer 154 to physically and electrically contact conductive layer 150, and conductive traces to fan-in or fan-out electrical connections if desired. While two redistribution layers (RDL) are shown formed over CCL 120, any number of insulating and conductive layers can be interleaved over the CCL to implement the desired signal routing.

A solder resist layer 160 is formed over insulating layer 154 and conductive layer 156 in FIG. 2k. Solder resist layer 160 can be formed using any of the materials and methods discussed above for insulating layers generally. In FIG. 2l, solder resist layer 160 has openings 162 formed therethrough to expose contact pads of conductive layer 156. Openings 162 can be formed by laser ablation, chemical etching, photolithography, or another suitable method.

In FIG. 2m, CCL 120 is deconstructed by separating conductive layers 124 from core 122. Conductive layer 124 can be separated from core 122 by mechanical peeling, thermal release, or another suitable means. Each side, top and bottom, of CCL 120 becomes a separate embedded trace substrate (ETS) 166. From here on, each side of CCL 120, as constructed above, is separately processed as its own panel or ETS 166.

In FIG. 2n, ETS 166 is oriented with conductive layer 124 exposed for removal. Removal of conductive layer 124 is illustrated as being done by a grinder 168, but chemical etching, laser ablation, or another suitable method is used in other embodiments. Removing conductive layer 124 exposes contact pads 136 and contact pads 112a of bridge die 104.

In FIG. 2o, ETS 166 is completed and ready to be used to form a semiconductor package or chiplet. ETS 166 in FIG. 20 can be used as a substrate to form any type of semiconductor package. In some embodiments, ETS 166 with double-sided bridge die 104 is the final product sold by a substrate manufacturer, and another manufacturer forms semiconductor packages using the ETS.

As one basic example of forming a chiplet with ETS 166, a pair of semiconductor die 170 is mounted onto contact pads 136 and contact pads 112a of bridge die 104 in FIG. 2p. Semiconductor die 170 are formed from a semiconductor wafer similar to wafer 100. Semiconductor die 170 are used for their active functionality implemented using transistors, diodes, and other circuit elements formed in or on the semiconductor die. Solder bumps 172 are reflowed between semiconductor die 170 and contact pads 136 and 112a to mechanically and electrically connect the semiconductor die to the contact pads. An underfill is used between semiconductor die 170 and the underlying substrate in some embodiments.

An encapsulant may also be deposited to cover semiconductor die 170, or with a top surface coplanar to the semiconductor die. The encapsulant material can be deposited using a paste printing, compressive molding, transfer molding, liquid encapsulant molding, vacuum lamination, spin coating, or another suitable applicator. The encapsulant can be liquid or granular polymer composite material, such as epoxy resin, epoxy acrylate, or polymer, with or without an added filler.

Each semiconductor die 170 is mounted over one of two opposing sides of bridge die 104 that have contact pads 112a formed thereon, and the semiconductor die are connected to each other through the bridge die. Semiconductor die 170 may each be disposed directly over one side of bridge die 104, or slightly outside of the footprint of the bridge die where a short interconnect is still possible. Because bridge die 104 is double-sided, semiconductor die 170 are not only coupled to each other through conductive layer 112 on the top side of the bridge die, as shown by signal path 176a, but also through conductive layer 114 on the bottom side of the bridge die in series with conductive layer 150, as shown by signal path 176b. Having signal paths on both sides of bridge die 104 allows a reduction in the overall pitch compared to bridge die with conductive traces on only one side, thus reducing manufacturing complexity and cost. The double-sided aspect of bridge die 104 can be used to double the total number of conductive signal paths at the same pitch from the prior art, to loosen the line pitch while keeping the same number of conductive signal paths, or to provide both benefits to a lesser degree.

An electrically conductive bump material is deposited over conductive layer 156 in openings 162 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 156 using a suitable attachment or bonding process. In one embodiment, the bump material is reflowed by heating the material above its melting point to form balls or bumps 178. In one embodiment, bump 178 is formed over an under-bump metallization (UBM) having a wetting layer, a barrier layer, and an adhesion layer.

Bump 178 can also be compression bonded or thermocompression bonded to conductive layer 156. Bump 178 represents one type of interconnect structure that can be formed over conductive layer 156. The interconnect structure can also use bond wires, conductive paste, stud bump, micro bump, or other electrical interconnect. In some embodiments, bumps 178 are formed by the ETS 166 manufacturer prior to beginning to form a semiconductor package or chiplet using the ETS. Bumps 172 on semiconductor die 170 can be formed in the same way and using the same materials as bumps 178.

FIG. 2p shows a completed chiplet 180 ready to be integrated into a larger device or semiconductor package. In most embodiments, a large ETS 166 is used to form a plurality of chiplets 180 at once. After completion of chiplets 180 or other semiconductor package on ETS 166 in FIG. 2p, the ETS and packages are singulated from each other by cutting through the ETS and any encapsulant or underfill, if used, to result in a plurality of the structures shown in FIG. 2p separate from each other. The defect rate for manufacturing chiplets 180 is improved by handling bridge die 104 using substrate 115. Carrier 115 is only removed after bridge die 104 is firmly fixed to the package substrate.

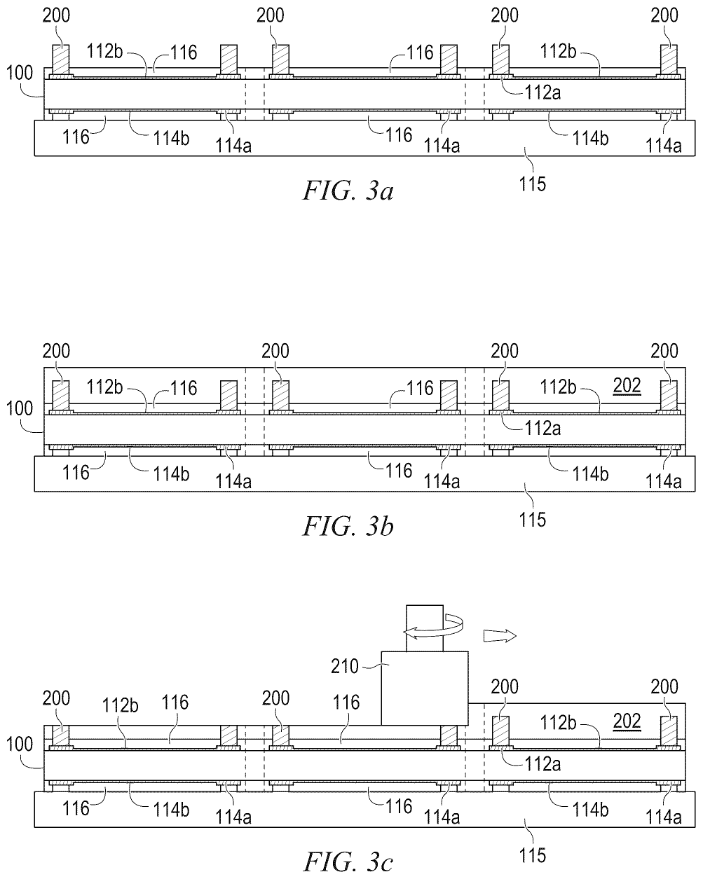

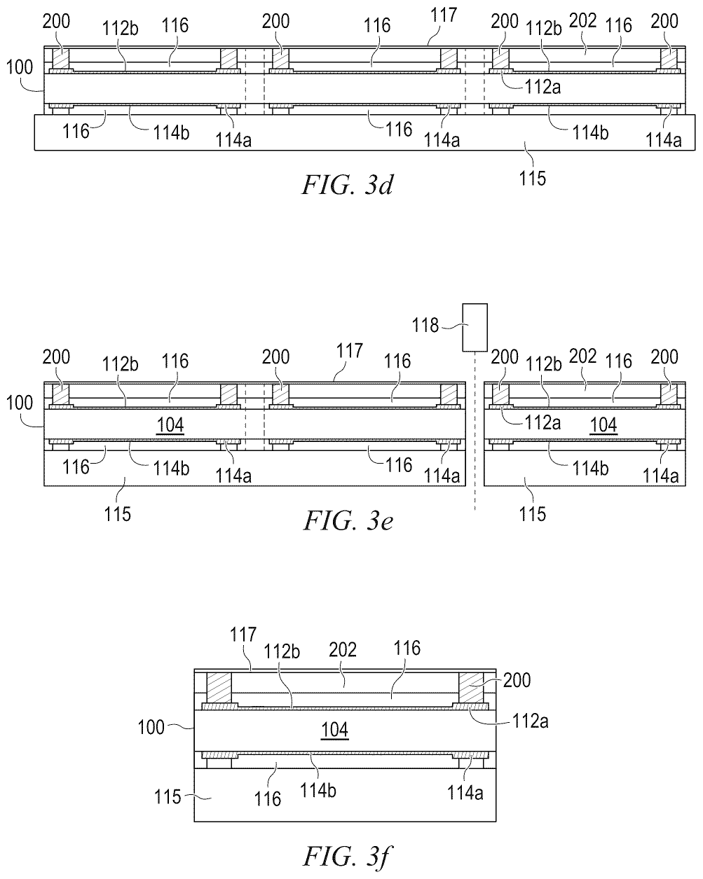

FIGS. 3a-3f illustrate an alternative embodiment for preparing bridge die 104. FIG. 3a continues from FIG. 1d. After mounting carrier 115, wafer 100 is flipped so that the carrier is on the bottom supporting the wafer. Conductive pillars 200 are formed on contact pads 112a in the openings of insulating layer 116. Conductive pillars 200 are formed using any of the methods and materials mentioned above for conductive layers. In one embodiment, the conductive material is deposited into mask openings, and then the mask is removed to leave conductive pillars 200. Conductive pillars 200 have a width and footprint that is aligned to and approximately the same size as respective openings in insulating layer 116. In other embodiments, conductive pillars 200 are formed with a wider footprint than the openings in insulating layer 116 so that the conductive pillars are formed directly on a top surface of the insulating layer.

Insulating layer 202 is formed over bridge die 104 and conductive pillars 200 in FIG. 3b. Insulating layer 202 is formed using any of the methods and materials described above for insulating layers or encapsulant generally. Insulating layer 202 completely covers the tops of conductive pillars 200. Insulating layer 202 is backgrinded in FIG. 3c to expose conductive pillars 200. Top surfaces of conductive pillars 200 and insulating layer 202 are made coplanar. In other embodiments, film-assisted molding or another suitable method is used to deposit insulating layer 202 while leaving conductive pillars 200 exposed and coplanar to the insulating layer.

In FIG. 3d, adhesive layer 117 is applied as described above. Adhesive layer 117 is attached onto insulating layer 202 and conductive pillars 200 instead of to insulating layer 116 as in the previous embodiments. Bridge die 104 and carrier 115 are singulated in FIG. 3e. FIG. 3f shows a completed bridge die 104 unit with conductive pillars 200. Conductive pillars 200 add an offset to improve the positioning of bridge die 104 in some package setups.

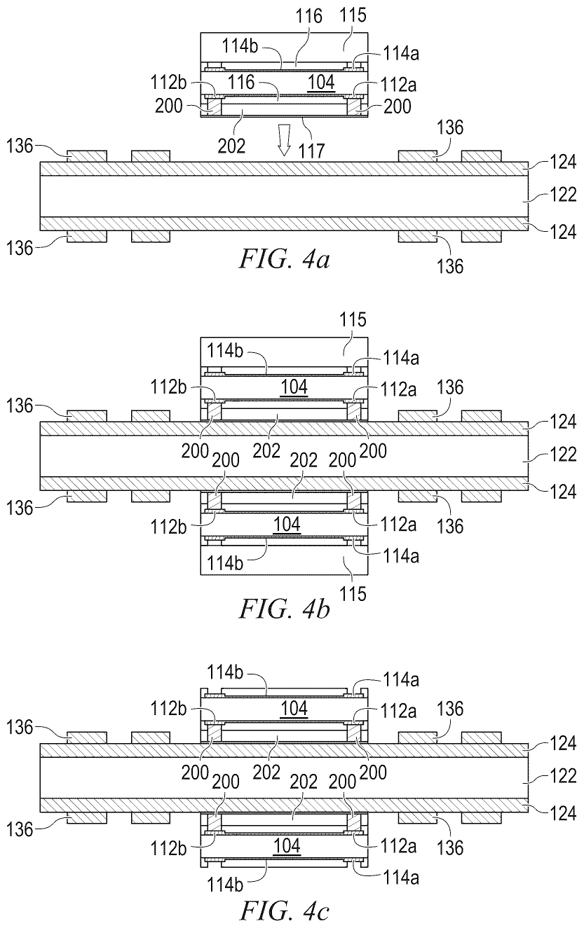

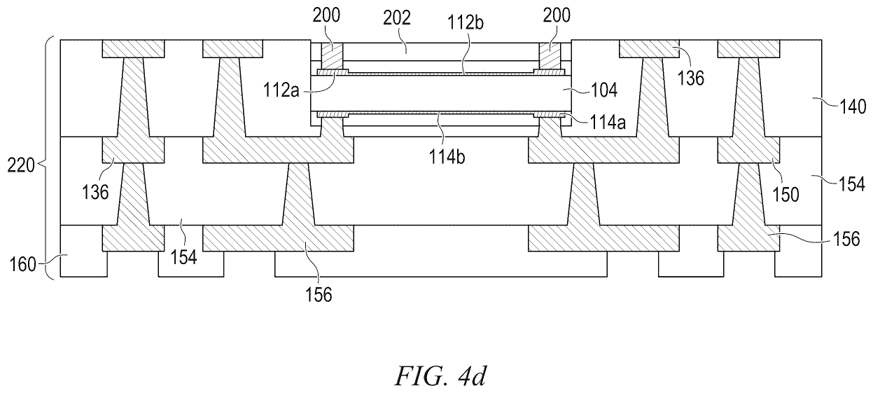

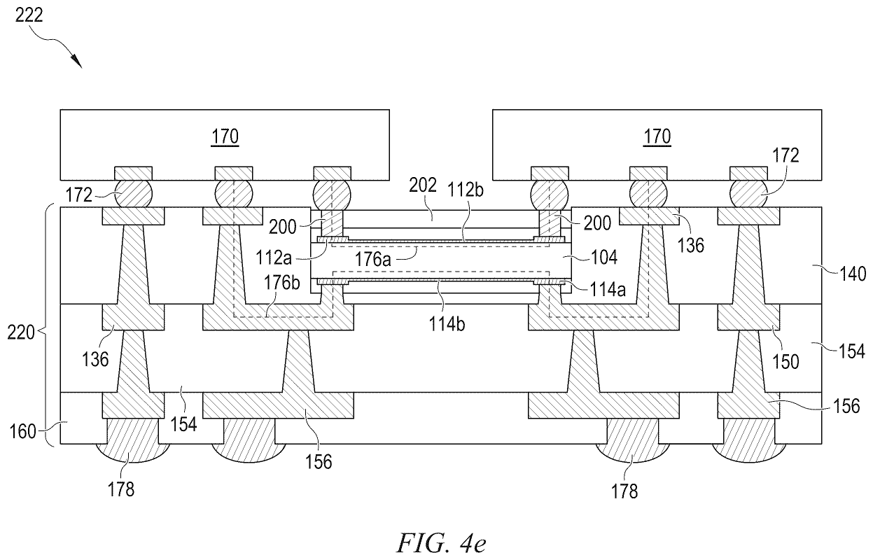

FIGS. 4a-4e illustrate including bridge die 104 with conductive pillars 200 in a semiconductor package. The process is substantially the same as shown in FIGS. 2a-20, but with pillars 200 adding an offset for bridge die 104. In FIG. 4a, bridge die 104 is disposed onto CCL 120 as in FIG. 2d. Pillars 200 are oriented toward CCL 120. In other embodiments, adhesive layer 117 is disposed on CCL 120 first, and then bridge die 104 is mounted to the CCL with carrier 115 but without adhesive layer 117 being pre-applied to the bridge die. FIG. 4b shows a bridge die 104 disposed on each side of CCL 120. Once bridge die 104 are secured to CCL 120, the portions of carrier 115 are removed in FIG. 4c as in FIG. 2f.

FIG. 4d shows a completed ETS 220 with bridge die 104 and conductive pillars 200 formed substantially as shown above. FIG. 4e shows a completed package 222 with ETS 220, again formed as illustrated above. Conductive pillars 200 provide a vertical offset, which can help with signal routing.

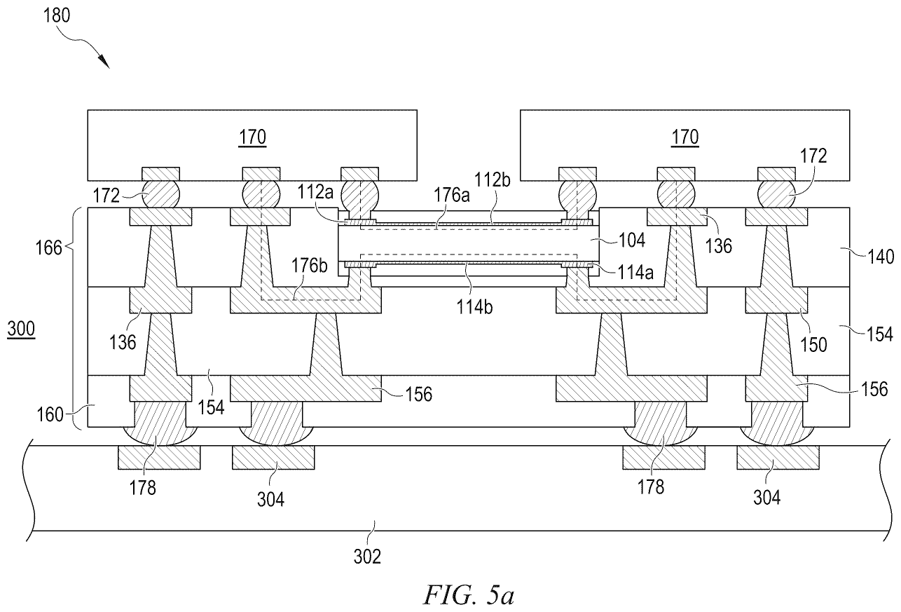

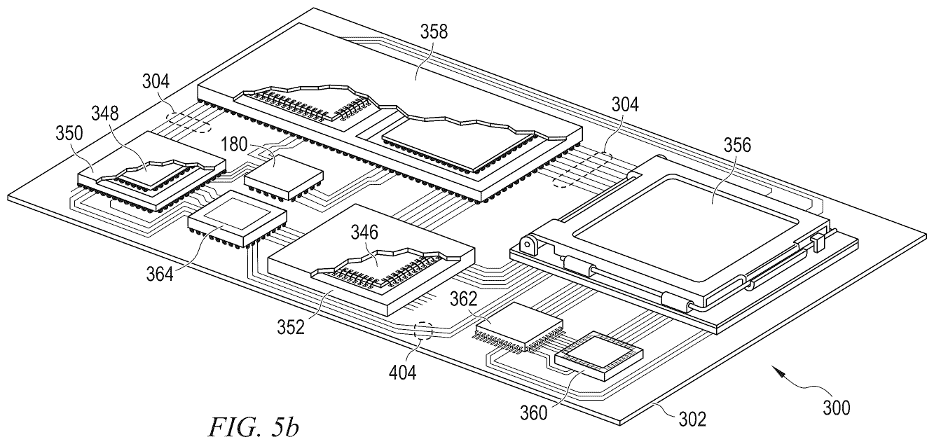

FIGS. 5a and 5b illustrate integrating the above-described semiconductor packages, e.g., chiplet 180, into a larger electronic device 300. FIG. 5a illustrates a partial cross-section of chiplet 180 mounted onto a printed circuit board (PCB) or other substrate 302 as part of electronic device 300. Solder bumps 178 are reflowed onto conductive layer 304 of PCB 302 to physically attach and electrically connect the chiplet to the PCB. In other embodiments, thermocompression or another suitable attachment and connection methods are used. In some embodiments, an adhesive or underfill layer is used between chiplet 180 and PCB 302. Semiconductor die 170 are electrically coupled to conductive layer 304 through ETS 166. ETS 166 also includes dual-sided bridge die 104 that electrically couples the two semiconductor die 170 to each other.

FIG. 5b illustrates electronic device 300 having a chip carrier substrate or PCB 302 with a plurality of semiconductor packages disposed on a surface of PCB 302, including chiplet 180. Electronic device 300 can have one type of semiconductor package, or multiple types of semiconductor packages, depending on the application. In other embodiments, chiplet 180 is incorporated as only one part of another larger semiconductor package, e.g., a system-in-package, before being incorporated into a larger electronic device 300.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor wafer;
forming a bridge die over the semiconductor wafer including a first contact pad on a first surface of the bridge die and a second contact pad on a second surface of the bridge die opposite the first surface;
attaching the semiconductor wafer to a first carrier;
singulating the semiconductor wafer and first carrier to separate the bridge die and a portion of the first carrier;
disposing the bridge die over a second carrier with the bridge die between the second carrier and the portion of the first carrier;
removing the portion of the first carrier after disposing the bridge die over the second carrier;
forming a first conductive layer on the second carrier;
forming a first insulating layer over the first conductive layer and bridge die;
forming an opening through the first insulating layer to expose the first conductive layer;
forming a second conductive layer over the first insulating layer, wherein the second conductive layer electrically couples the first conductive layer to the first contact pad of the bridge die;
removing the second carrier; and
mounting a first semiconductor die electrically coupled to the first conductive layer and the second contact pad of the bridge die.

2. The method of claim 1, further including forming a second insulating layer over the first insulating layer and second conductive layer.

3. The method of claim 2, further including forming a third conductive layer over the second insulating layer, wherein the third conductive layer includes a conductive via extending through the second insulating layer to contact the second conductive layer.

4. The method of claim 1, further including forming a conductive pillar on the bridge die.

5. The method of claim 4, wherein removing the second carrier includes:
separating a core of the second carrier from a copper layer of the second carrier; and
removing the copper layer from the first insulating layer, first conductive layer, and bridge die after separating the core from the copper layer.

6. The method of claim 1, further including mounting a second semiconductor die electrically coupled to the first semiconductor die through the first contact pad and second contact pad in parallel.

7. A method of making a semiconductor device, comprising:
providing a double-sided bridge die including a first contact pad on a first surface of the bridge die and a second contact pad on a second surface of the bridge die;
attaching the double-sided bridge to a first carrier;
disposing the bridge die and first carrier over a second carrier;
removing the first carrier after disposing the bridge die over the second carrier;
forming a first conductive layer on the second carrier;
forming an insulating layer over the first conductive layer and bridge die;
forming an opening through the insulating layer to expose the first conductive layer;
forming a second conductive layer over the insulating layer, wherein the second conductive layer electrically couples the first conductive layer to the first contact pad of the bridge die; and
removing the second carrier to expose the first conductive layer and the second contact pad of the bridge die.

8. The method of claim 7, further including forming a second insulating layer over the first insulating layer and second conductive layer.

9. The method of claim 8, further including forming a third conductive layer over the second insulating layer, wherein the third conductive layer includes a conductive via extending through the second insulating layer to contact the second conductive layer.

10. The method of claim 7, wherein the second carrier is a copper-clad laminate (CCL).

11. The method of claim 7, further including forming a conductive pillar on the bridge die.

12. The method of claim 7, further including forming the bridge die to include:
a third contact pad on the first surface of the bridge die;
a first conductive trace on the first surface of the bridge die extending from the first contact pad to the third contact pad;
a fourth contact pad on the second surface of the bridge die; and
a second conductive trace on the second surface of the bridge die extending from the second contact pad to the fourth contact pad.

13. The method of claim 12, further including forming the second conductive layer to electrically couple the third contact pad to the first conductive layer.

14. A method of making a semiconductor device, comprising:
providing a double-sided bridge die including a first contact pad on a first surface of the bridge die and a second contact pad on a second surface of the bridge die;
disposing the bridge die over a first carrier;
disposing the bridge die and first carrier over a second carrier;
removing the first carrier;
forming a first conductive layer over the second carrier;
forming a second conductive layer, wherein the second conductive layer electrically couples the conductive layer to the first contact pad of the bridge die; and
removing the second carrier to expose the first conductive layer and the second contact pad of the bridge die.

15. The method of claim 14, further including forming a conductive pillar on the bridge die.

16. The method of claim 14, further including forming a third conductive layer over the second conductive layer, wherein the third conductive layer includes a conductive via in contact with the second conductive layer.

17. The method of claim 14, wherein the second carrier is a copper-clad laminate (CCL).

18. The method of claim 17, wherein removing the second carrier includes:
separating a core of the CCL from a copper layer of the CCL; and
removing the copper layer from the first conductive layer and bridge die after separating the core from the copper layer.

19. The method of claim 14, further including forming the bridge die to include:
a third contact pad on the first surface of the bridge die;
a first conductive trace on the first surface of the bridge die extending from the first contact pad to the third contact pad;
a fourth contact pad on the second surface of the bridge die; and
a second conductive trace on the second surface of the bridge die extending from the second contact pad to the fourth contact pad.

20. A semiconductor device, comprising:
a first double-sided bridge die including a first contact pad on a first surface of the first double-sided bridge die and a second contact pad on a second surface of the first double-sided bridge die;
a first carrier attached to the first double-sided bridge die, wherein a footprint of the first carrier is approximately equal to a footprint of the first double-sided bridge die; and
a second carrier, wherein the first double-sided bridge die is mounted to a surface of the second carrier with the first double-sided bridge die between the first carrier and second carrier.

21. The semiconductor device of claim 20, further including an insulating layer formed over the first double-sided bridge die and first carrier.

22. The semiconductor device of claim 20, further including a second double-sided bridge die disposed over the second carrier opposite the first double-sided bridge die.

23. The semiconductor device of claim 22, further including a third carrier attached to the second double-sided bridge die, wherein a footprint of the third carrier is approximately equal to the footprint of the first double-sided bridge die.

24. The semiconductor device of claim 20, further including a conductive pillar formed on the first double-sided bridge die and disposed between the first double-sided bridge die and second carrier.

25. The semiconductor device of claim 20, further including a conductive layer formed on the second carrier around the first double-sided bridge die.
